(19) United States
(12) Patent Application Publication
(10) Pub. No.: US 2024/0429084 A1
(43) Pub. Date: Dec. 26, 2024

(54) SUBSTRATE PROCESSING APPARATUS

(71) Applicant: Samsung Electronics Co., Ltd., Suwon-si (KR)

(72) Inventors: Youngbok LEE, Suwon-si (KR); Sangchul HAN, Suwon-si (KR); Yihwan KIM, Suwon-si (KR); Yeontae KIM, Suwon-si (KR); Namjin CHO, Suwon-si (KR)

(73) Assignee: Samsung Electronics Co., Ltd., Suwon-si (KR)

(21) Appl. No.: 18/409,082

(22) Filed: Jan. 10, 2024

(30) Foreign Application Priority Data
Jun. 22, 2023 (KR) 10-2023-0080382

(51) Int. Cl. H01L 21/683; H01L 21/67

(52) U.S. Cl. CPC H01L 21/6833; H01L 21/67017

(57) ABSTRACT

A substrate processing apparatus that includes a mounting table including an insulator having a loading surface; a gas distribution unit including injection holes; and a gas supply unit that supplies process gas. An electrode and a heater are embedded in the insulator, and a dielectric layer covers the loading surface. The dielectric layer includes a lower material layer, an intermediate material layer, and an upper material layer. The intermediate material layer has a third thickness, greater than each of a first thickness of the lower material layer and a second thickness of the upper material layer. The intermediate material layer has a third dielectric constant, greater than each of a first dielectric constant of the lower material layer and a second dielectric constant of the upper material layer.

### CROSS-REFERENCE TO RELATED APPLICATION(S)

This application claims benefit of priority to Korean Patent Application No. 10-2023-0080382, filed on Jun. 22, 2023 in the Korean Intellectual Property Office, the entirety of which is incorporated herein by reference.

### BACKGROUND

The present disclosure relates to a substrate processing apparatus.

In order to manufacture a semiconductor device, a series of semiconductor processes such as for example deposition, etching, cleaning, and the like may be performed. Semiconductor processes may be performed after adsorbing a substrate to a substrate mounting table (e.g., a wafer chuck table) provided in a process chamber. A substrate in which warpage has occurred as a result of repeated application of semiconductor processes may not be uniformly adsorbed to the substrate mounting table.

### SUMMARY

Embodiments of the inventive concepts provide a substrate processing apparatus with a mounting table capable of uniformly adsorbing a substrate.

Embodiments of the inventive concepts provide a substrate processing apparatus that includes a mounting table including an insulator having a loading surface on which a substrate is loaded, the loading surface includes protrusions; an electrode and a heater are embedded in the insulator; a dielectric layer covering the loading surface; a gas distribution unit including injection holes facing the mounting table; a gas supply unit that supplies process gas through the gas distribution unit; a first power supply unit that applies a first voltage to the electrode; and a second power supply unit that applies a second voltage to the heater. The dielectric layer includes a lower material layer, an intermediate material layer, and an upper material layer, sequentially stacked on the loading surface. The intermediate material layer has a third thickness, greater than each of a first thickness of the lower material layer and a second thickness of the upper material layer. The intermediate material layer has a third dielectric constant, greater than each of a first dielectric constant of the lower material layer and a second dielectric constant of the upper material layer.

Embodiments of the inventive concepts further provide a substrate processing apparatus that includes a mounting table having a pocket region in which a substrate is loaded, the mounting table including an insulator having protrusions and a seal band in the pocket region; an electrode embedded in the insulator; a dielectric layer conformally extending along a surface of each of the protrusions and the seal band; a gas distribution unit including injection holes facing the mounting table; a gas supply unit that supplies process gas through the gas distribution unit; and a power supply unit that applies a voltage to the electrode. The dielectric layer includes a lower material layer, an intermediate material layer, and an upper material layer. A thickness of the intermediate material layer is greater than a sum of a thickness of the lower material layer and a thickness of the upper material layer.

Embodiments of the inventive concepts still further provide a substrate processing apparatus that includes a mounting table including an insulator having a loading surface on which a substrate is loaded; an electrode and a heater embedded in the insulator; a dielectric layer covering the loading surface; a gas distribution unit including injection holes facing the mounting table; a gas supply unit that supplies process gas through the gas distribution unit; a first power supply unit that applies a first voltage to the electrode; and a second power supply unit that applies a second voltage to the heater. The dielectric layer includes a lower material layer, an intermediate material layer, and an upper material layer, sequentially stacked on the loading surface. A thickness of the intermediate material layer is greater than a thickness of the lower material layer and a thickness of the upper material layer. A hardness of the intermediate material layer is greater than hardness of the upper material layer.

### BRIEF DESCRIPTION OF DRAWINGS

The above and other aspects, features, and advantages of the present disclosure will be more clearly understood from the following detailed description, taken in conjunction with the accompanying drawings:

FIG. 1 is a schematic diagram illustrating a substrate processing apparatus according to some example embodiments of the inventive concepts;

FIG. 2 is a cross-sectional view illustrating a substrate processing apparatus according to some example embodiments of the inventive concepts;

FIG. 3A is a cross-sectional view illustrating a mounting table applicable to a substrate processing apparatus according to some example embodiments of the inventive concepts;

FIG. 3B is a partially enlarged view illustrating region ‘A’ in FIG. 3A;

FIG. 4 is a partially enlarged view illustrating a dielectric layer of some other example embodiments;

FIG. 5A is a diagram of modeling elements disposed between an electrode of an electrostatic chuck and a substrate for simulating chucking force acting on a substrate;

FIG. 5B is a circuit diagram illustrating elements of FIG. 5A as an equivalent circuit;

FIG. 5C is a graph illustrating chucking force of some example embodiments and a Comparative Example;

FIG. 6A is a partially enlarged view illustrating an electrostatic adsorption state of a substrate in a Comparative Example;

FIG. 6B is a graph illustrating a limit of an increase in chucking voltage in a Comparative Example; and

FIG. 7 is a partially enlarged view illustrating an electrostatic adsorption state of a substrate in some example embodiments.

### DETAILED DESCRIPTION

Hereinafter, with reference to the accompanying drawings, preferred embodiments of the present inventive concepts will be described as follows. Unless otherwise specified, in this specification, terms such as ‘upper portion,’ ‘upper surface,’ ‘lower portion,’ ‘lower surface,’ ‘side surface,’ and the like, are based on the drawings, and may actually vary depending on a direction in which the components are arranged.

Also, an ordinal number such as “first,” “second,” “third”, and the like may be used as a label of specific elements, steps, directions, and the like to distinguish various elements, steps, and directions from each other. Terms not described using “first”, “second”, and the like, in the specification may still be referred to as “first” or “second” in the claims. Also, a term referenced by a particular ordinal number (e.g., “first” in a particular claim) may be recited elsewhere by a different ordinal number (e.g., “second” in a specification or the other claim).

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

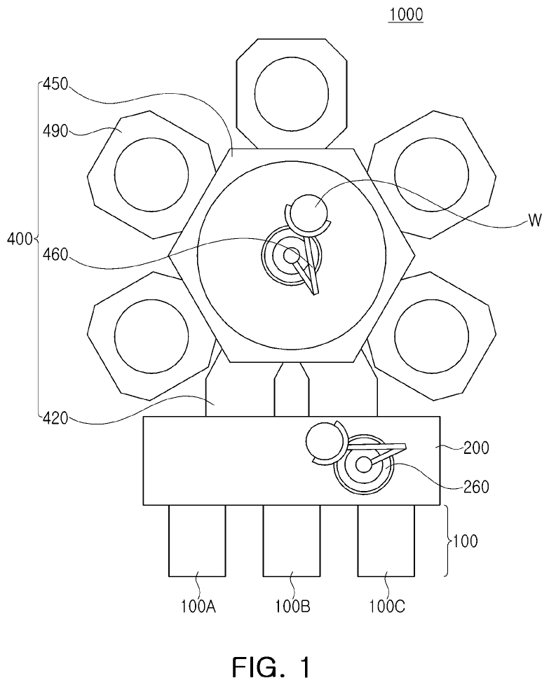

FIG. 1 is a schematic diagram illustrating a substrate processing system 1000 according to some example embodiments of the inventive concepts.

Referring to FIG. 1, the substrate processing system 1000 according to some example embodiments may include a load port 100, a transfer module 200, a process module 400, and a control unit (not shown).

The load port 100 may include a plurality of ports 100A, 100B, and 100C into which a storage container of a substrate W is loaded. The storage container may have an internal space capable of accommodating a plurality of substrates W. A substrate W drawn out from the wafer storage container loaded in the plurality of ports 100A, 100B, and 100C by the transfer module 200 may be transported to the process module 400.

The transfer module 200 may be configured to transport a substrate W such as a semiconductor wafer between the load port 100 and the process module 400. The transfer module 200 may have an internal space separated from the outside, and the transfer robot 260 for transferring the substrate W may be included in the internal space. The transfer robot 260 may include an arm capable of moving in horizontal and vertical directions and a rotating plate to which the arm is fixed and capable of rotating. The transfer robot 260 may draw out the substrate W from a container of the load port 100 and transport the same to the process module 400 or draw out the substrate W from the process module 400 and transport the same to the load port 100.

The load lock chamber 420 may be configured to depressurize or pressurize an internal space to a vacuum state. The transfer chamber 450 may have an internal space connectable to the load lock chamber 420 and the process chamber 490, and a transfer robot 460 configured to transport the substrate W may be provided in the internal space.

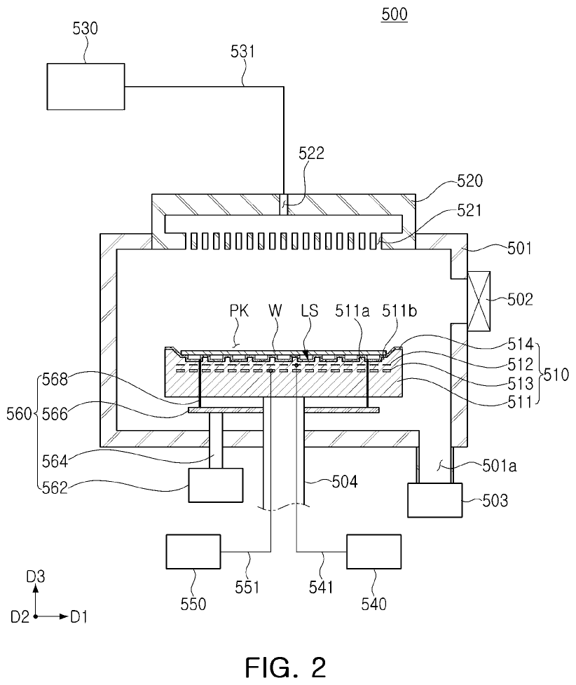

The process chamber 490 may be a deposition chamber for performing a physical vapor deposition (PVD), chemical vapor deposition (CVD), or atomic layer deposition (ALD) process, an etching chamber for performing a plasma etching process, and the like, but the inventive concepts are not limited thereto. The process chamber 490 may be a chamber for another process to which an electrostatic chuck is applied as a holding device for the substrate W, for example, a process other than deposition and etching. It should be understood that the process chamber 490 shown in FIG. 1 may correspond to a substrate processing apparatus 500 shown in FIG. 2.

FIG. 2 is a cross-sectional view illustrating a substrate processing apparatus 500 according to some example embodiments of the inventive concepts.

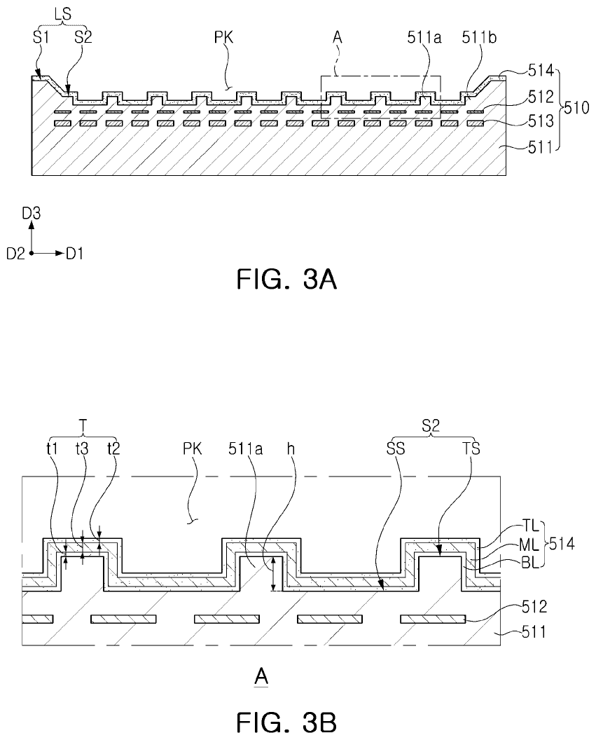

FIG. 3A is a cross-sectional view illustrating a mounting table 510 that may be applied to, or be part of, the substrate processing apparatus 500 according to some example embodiments of the inventive concepts, and FIG. 3B is a partially enlarged view illustrating region A in FIG. 3A.

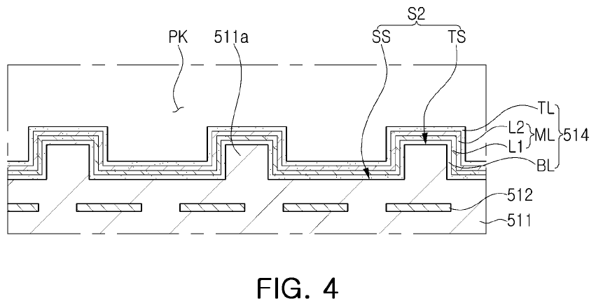

FIG. 4 is a partially enlarged view illustrating a dielectric layer 514 of some example embodiments of the inventive concepts.

Referring to FIGS. 2, 3A, 3B, and 4, a substrate processing apparatus 500 according to some example embodiments may include a mounting table 510, a gas distribution unit 520, a gas supply unit 530, and a first power supply unit 540. According to some example embodiments, the substrate processing apparatus 500 may further include a second power supply unit 550 and/or a substrate elevating unit 560.

The substrate processing apparatus 500 may include a chamber 501 providing an internal space in which processing of a substrate W is performed and in which a mounting table 510, a gas distribution unit 520, a gas supply unit 530, and the like are disposed. The chamber 501 may provide a sealed space in which processing of the substrate W is performed. The chamber 501 may be provided in various forms depending on a shape and size of the substrate W. A gate 502 configured to open and close the internal space of the chamber 501 may be provided on one side of the chamber 501. The chamber 501 may be connected to the transfer chamber 450 shown in FIG. 1 through a gate 502. The substrate W may be inserted into or removed from the chamber 501 through the gate 502. The chamber 501 may be connected to an exhaust device 503 through an exhaust port 501a. The exhaust device 503 may be configured to control internal pressure of the chamber 501, such as a vacuum pump. The mounting table 510 may include an electrostatic chuck configured to adsorb and hold the substrate W by Coulomb force. The mounting table 510 may be disposed on a support shaft 504. The support shaft 504 may be raised and lowered by a lift control unit such as, for example, a linear actuator. The mounting table 510 may include an insulator 511, an electrode 512, a heater 513, and a dielectric layer 514.

The mounting table 510 may be disposed below the chamber 501 to hold the substrate W, For example, the mounting table 510 may have a pocket region PK in which the substrate W is loaded.

The insulator 511 may provide a loading surface LS on which the substrate W is loaded. The insulator 511 may include protrusions 511a and a seal band 511b disposed on the loading surface LS. A height h of each of the protrusions 511a and the seal band 511b may be within a range of about 20 μm to about 40 μm, but the inventive concepts are not limited thereto. The height h of each of the protrusions 511a and the seal band 511b may be variously modified according to a size and material of the substrate W, the type of processing process, and the like. The loading surface LS may have a first surface S1, and a second surface S2 recessed from the first surface, and the protrusions 511a and the seal band 511b may be arranged on a second surface S2 or in a pocket region PK. The pocket region PK may be defined by a step between the first surface S1 and the second surface S2. The protrusions 511a and the seal band 511b may support the substrate W loaded on the mounting table 510. For example, the seal band 511b may support an edge of the substrate W at a corner of the second surface S2. The insulator 511 may include a ceramic having excellent heat resistance, for example, at least one of aluminum nitride (AlN), aluminum oxide (Al₂O₃), and boron nitride (RN).

Each of the electrode 512 and the heater 513 may be embedded in the insulator 511. The electrode 512 and the heater 513 may include metal such as, for example, tungsten (W), copper (Cu), nickel (Ni), molybdenum (Mo), titanium (Ti), a nickel-chromium alloy (Ni—Cr alloy), a nickel-aluminum alloy (Ni—Al alloy), or the like, or a conductive ceramic such as tungsten carbide (WC), molybdenum carbide (MoC), titanium nitride (TiN), or the like, but the inventive concepts are not limited thereto. Each of the electrode 512 and the heater 513 may be connected to voltage supply units (e.g., first and second power supply units) 540 and 550 through feed lines 541 and 551. For example, a first voltage may be applied to the electrode 512 from the first power supply unit 540 through the first feed line 541. When a first voltage is applied to the electrode 512, the substrate W may be adsorbed to a loading surface LS by Coulomb force. For example, a second voltage may be applied to the heater 513 from the second power supply unit 550 through the second feed line 551. The heater 513 is a resistance heating element, and can generate heat when a second voltage is applied.

The dielectric layer 514 may be formed to cover a loading surface LS. The dielectric layer 514 may conformally extend along surfaces of each of the protrusions 511a and the seal band 511b of the loading surface LS. For example, the dielectric layer 514 may cover a top surface TS of each of protrusions 511a and a seal band 511b, and extend along a spaced surface SS between the protrusions 511a, adjacent to each other, and between the seal band 511b and the protrusions 511a, adjacent to each other. That is, the dielectric layer 514 may extend between the substrate W and the insulator 511, and between the substrate W and the electrode 512. At least a portion of the dielectric layer 514 covering the top surface TS of each of the protrusions 511a and the seal band 511b may directly contact the substrate W. According to some example embodiments, the dielectric layer 514 may cover an entirety of the loading surface LS, but the present concepts are not limited thereto.

The dielectric layer 514 may include a lower material layer BL, an intermediate material layer ML, and an upper material layer TL, sequentially stacked on the loading surface LS. In some example embodiments according to the inventive concepts, by introducing the intermediate material layer ML, chucking force by the Coulomb force may be improved, without increasing a voltage applied to the electrode 512. For example, a voltage applied to the electrode 512 from the first power supply unit 540 may be a DC voltage of about 1000V or less. The intermediate material layer ML may be formed of a material having higher permittivity than the lower material layer BL and the upper material layer TL. For example, the intermediate material layer ML may have a third dielectric constant, greater than each of a first dielectric constant of the lower material layer BL and a second dielectric constant of the upper material layer TL. For example, the third dielectric constant may be twice or more each of the first dielectric constant and the second dielectric constant. The intermediate material layer ML may include, for example, at least one of silicon nitride (Si₃N₄), aluminum oxide (Al₂O₃), zirconia (ZrO₂), and hafnium oxide (HfO₂).

As shown in FIG. 4, the intermediate material layer ML of some example embodiments may include a first material layer L1 and a second material layer L2. Each of the first material layer L1 and the second material layer L2 may be formed of a material having higher permittivity than the lower material layer BL and the upper material layer TL. According to some example embodiments, the intermediate material layer ML may be formed of two or more material layers.

The lower material layer BL may be formed of a material having excellent adhesion to the insulator 511. The lower material layer BL may be interposed between the intermediate material layer ML and the insulator 511 to improve adhesion. The upper material layer TL is a layer, directly in contact with a substrate W, and may be formed of a material having low hardness in order to reduce or minimize damage applied to the substrate W. For example, the hardness of the intermediate material layer ML may be greater than that of the upper material layer TL. The lower material layer BL and the upper material layer TL may include, for example, silicon dioxide (SiO₂).

A thickness t3 of the intermediate material layer ML may be greater than a thickness t1 of the lower material layer BL and a thickness t2 of the upper material layer TL. The thickness t3 of the intermediate material layer ML may be greater than a sum of the thickness t1 of the lower material layer BL and the thickness t2 of the upper material layer TL. The thickness t3 of the intermediate material layer ML may be about 60% or more of a total thickness T of the dielectric layer 514, for example, and may be within a range of about 60% to about 90%, about 60% to about 80%, or about 70% to about 80%. When the thickness t3 of the intermediate material layer ML is less than about 60% of the total thickness T of the dielectric layer 514, an effect of increasing chucking force may be insignificant. When the thickness t3 of the intermediate material layer ML exceeds about 90% of the total thickness T of the dielectric layer 514, a ratio of the lower material layer BL may be reduced or minimized so that the adhesion thereof to the intermediate material layer ML and the insulator 511 may be decreased, or a ratio of the upper material layer TL may be reduced or minimized, so that a substrate W may be damaged when the substrate W is adsorbed. The total thickness T of the dielectric layer 514 may be within a range of about 1 μm to about 10 μm, from about 1 μm to about 8 μm, or from about 1 μm to about 5 μm. When the total thickness T of the dielectric layer 514 exceeds about 10 μm, the chucking force may be reduced or minimized.

The gas distribution unit 520 may be disposed above a chamber 501, and may include injection holes 521 toward the mounting table 510. The gas distribution unit 520 may be grounded or connected to a DC power source so that a constant DC voltage is applied. The gas distribution unit 520 may be configured to uniformly distribute process gases supplied from the gas supply unit 530 to the chamber 501. The gas distribution unit 520 may be connected to a gas supply pipe 531 through a gas inlet 522. Process gases supplied from the gas supply unit 530 may be distributed in the chamber 501 through injection holes 521 of the gas distribution unit 520. The gas supply unit 530 may provide process gases for processing such as deposition, etching, cleaning, and the like. For example, the gas supply unit 530 may supply reactive gases for a CVD process.

According to some example embodiments, a substrate elevating unit 560 configured to facilitate a transfer of a substrate W loaded on the mounting table 510 may be provided. The substrate elevating unit 560 may position the substrate W at a position that is easily accessible by a robot arm, or the like. The substrate elevating unit 560 may include an actuator 562, an elevating shaft 564, a support 566, and lift pins 568. The lift pins 568 may be fixed on the support 566, and movably disposed through pin holes of the mounting table 510. A support 566 may be disposed on a shaft 564 that is raised and lowered by an actuator 562.

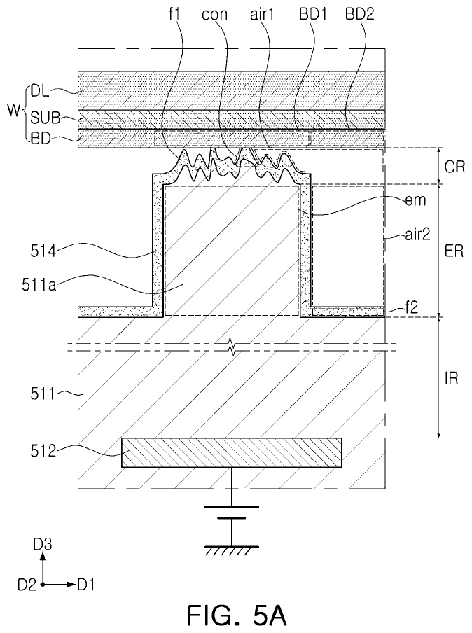

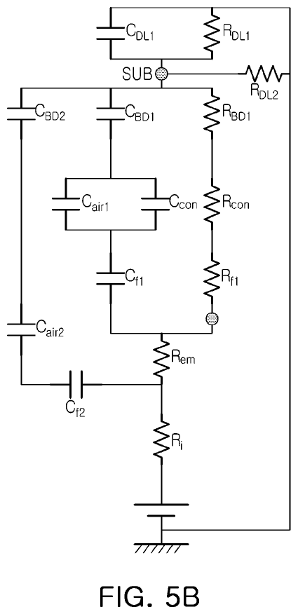

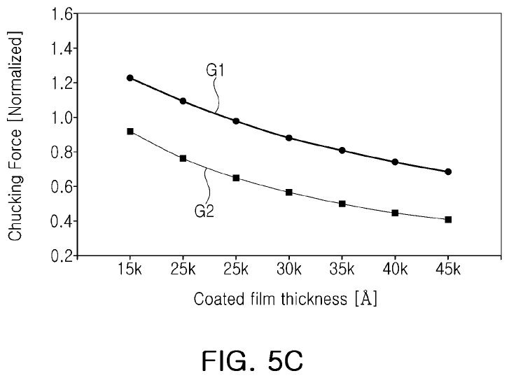

FIG. 5A is a diagram modeling elements disposed between an electrode of an electrostatic chuck and a substrate for simulating a Johnsen-Rahbek (J-R) chucking force acting on a substrate, FIG. 5B is a circuit diagram illustrating the elements of FIG. 5A as an equivalent circuit, and FIG. 5C is a graph for illustrating chucking forces of some example embodiments of the inventive concepts and Comparative Examples.

Referring to FIGS. 5A and 5B, a contact region CR, an embossed region ER, and an insulating region IR may be defined between the electrode 512 and the substrate W.

The substrate W may include a wafer SUB, a deposition layer DL, and a backside protective layer BD. The wafer SUB may be, for example, a silicon wafer used to manufacture a semiconductor device such as a semiconductor integrated circuit IC.

The deposition layer DL may include a material such as an amorphous carbon layer (ACL), SiO₂, or the like. ‘C_{DL1}’ is capacitance of SiO₂, ‘R_{DL1}’ is resistance of SiO₂, and ‘R_{DL2}’ is resistance of the ACL.

The backside protective layer BD is for reducing or preventing damage to a rear surface of the wafer SUB, and may include a material such as SiO₂. The backside protective layer BD may be divided into a ‘BD1’ region overlapping a protrusion 511a of the insulator 511 and a ‘BD2’ region overlapping an air gap (e.g., ‘air2’) on both sides of the protrusion 511a. ‘C_{BD1}’ is capacitance of the ‘BD1’ region, ‘R_{DB1}’ is resistance of the ‘BD1’ region, and ‘C_{BD2}’ is capacitance of the ‘BD2’ region.

The contact region CR is a region in which an upper end of the protrusion 511a and the substrate W are in contact, and may be divided into a ‘con’ region in which a rough surface of the protrusion 511a and the substrate W are in contact, an ‘air 1’ region in contact with an air gap around the rough surface of the protrusion 511a, and a ‘f1’ region in which the dielectric layer 514 forms a thin film. ‘Cₐᵢᵣ₁’ is capacitance of the ‘air1’ region, ‘C_{con}’ is capacitance of the ‘con’ region, ‘R_{con}’ is resistance of the ‘con’ region, ‘R_{f1}’ is a resistance of the ‘f1’ region, and ‘C_{f1}’ is capacitance of the ‘f1’ region.

The embossed region ER may be divided into an ‘em’ region corresponding to a body of the protrusion 511a, an ‘air2’ region, which is an air gap therearound, and a ‘f2’ region in which the dielectric layer 514 forms a thin film below the ‘air2’ region. ‘Cₐᵢᵣ₂’ is capacitance of the ‘air2’ region, ‘Rₑₘ’ is a resistance of the ‘em’ region, and ‘C_{f2}’ is capacitance of the ‘f2’ region.

The insulating region IR may be defined by an insulator 511 filling a space between the electrode 512 and the embossed region ER. ‘Rᵢ’ is resistance of the insulator 511 filling the gap between the electrode 512 and the embossed region ER.

Referring to FIGS. 5B and 5C together, as a result of simulation using the equivalent circuit of FIG. 5B, a change in chucking force according to a thickness of the dielectric layer 514 may be known. ‘G1’ represents chucking force of some example embodiments in which the dielectric layer 514 includes a lower material layer BL, an intermediate material layer ML, and an upper material layer TL. For example, each of the lower material layer BL and the upper material layer TL was set to about 1 k Å. ‘G2’ represents chucking force of a Comparative Example in which the dielectric layer 514 includes a single material layer. Referring to ‘G1’ and ‘G2’, the chucking force of some example embodiments of the inventive concepts is increased compared to the comparative example regardless of the thickness of the dielectric layer 514.

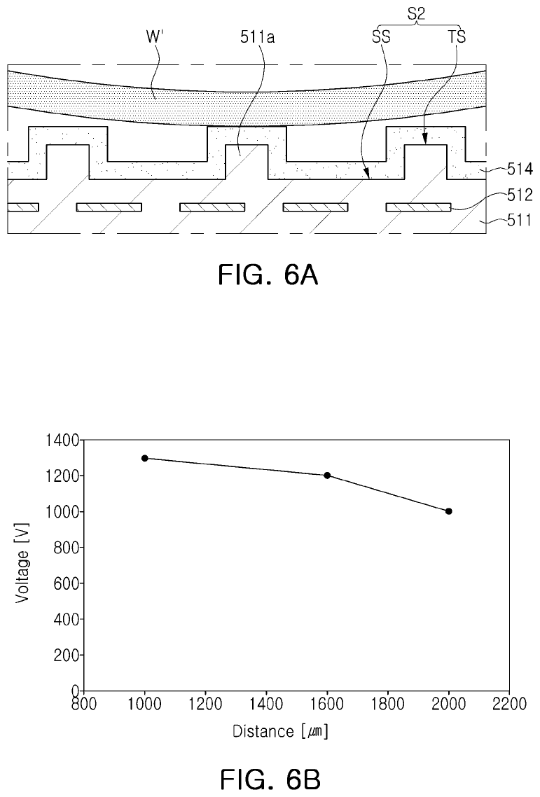

FIG. 6A is a partially enlarged view illustrating an electrostatic adsorption state of a substrate in a Comparative Example, and FIG. 6B is a graph illustrating a limit of an increase in chucking voltage in the Comparative Example.

Referring to FIGS. 6A and 6B, a dielectric layer 514 of the Comparative Example is formed of a single material layer, or may be composed of other combinations of material layers, other than a lower material layer BL, an intermediate material layer ML, and an upper material layer TL and/or may be composed of other combinations of material layers not having the above-described thicknesses and physical properties. Depending on a degree of warpage, a portion of a substrate W may be spaced apart from protrusions 511a of an insulator 511. As described above, when the warped substrate W is not uniformly adsorbed, process precision may decrease, and process errors may increase. When a voltage is applied to an electrode 512 to uniformly adsorb the warped substrate W′, discharging may occur above a certain voltage, resulting in unstable chucking, FIG. 6B is a graph illustrating a threshold voltage according to a distance between a gas distribution unit 520 and a mounting table 510. As shown, the threshold voltage at which discharging occurs decreases, as the distance between the gas distribution unit 520 and the mounting table 510 increases.

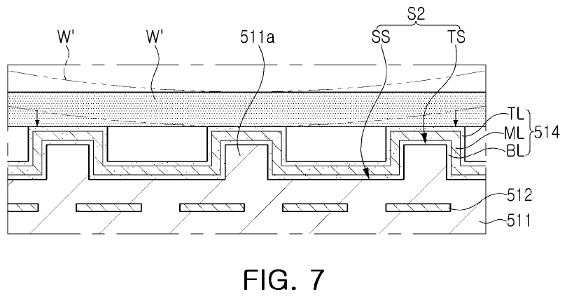

FIG. 7 is a partially enlarged view illustrating an electrostatic adsorption state of a substrate in some example embodiments.

Referring to FIG. 7, a dielectric layer 514 of some example embodiments may include an intermediate material layer ML having high permittivity. A dielectric constant of an intermediate material layer ML may be twice or more than a dielectric constant of each of a lower material layer BL and an upper material layer TL. The intermediate material layer ML may include, for example, silicon nitride (Si₃N₄). The intermediate material layer ML may improve chucking force by Coulomb force without increasing the voltage applied to the electrode 512. Accordingly, the warped substrate W may be uniformly adsorbed to protrusions 511a by an increase in the chucking force.

The lower material layer BL may be formed of a material having excellent adhesion to the insulator 511. The upper material layer TL is a layer directly contacting the substrate W, and may be formed of a material having low hardness in order to minimize damage applied to the substrate W. The lower material layer BL and the upper material layer TL include, for example, silicon dioxide (SiO₂).

A thickness of the intermediate material layer ML may be greater than a thickness of the lower material layer BL and a thickness of the upper material layer TL. The thickness of the intermediate material layer ML may be within a range of about 70% to about 80% of a total thickness T of the dielectric layer 514. The total thickness of dielectric layer 514 may be within a range of about 1 μm to about 5 μm.

As set forth above, according to some example embodiments of the inventive concepts, by introducing a dielectric layer capable of increasing a chucking force of an electrostatic chuck on a loading surface of a mounting table, a substrate processing apparatus provided with a mounting table capable of uniformly adsorbing a substrate may be provided.

The various and advantageous advantages and effects of the inventive concepts are not limited to the above description, and may be more easily understood in the course of describing the specific embodiments of the inventive concepts. While example embodiments have been shown and described above, it will be apparent to those skilled in the art that modifications and variations could be made without departing from the scope of the inventive concepts, as defined by the appended claims.

What is claimed is:

1. A substrate processing apparatus, comprising:
a mounting table including an insulator having a loading surface on which a substrate is loaded, the loading surface including protrusions;
an electrode and a heater embedded in the insulator;
a dielectric layer covering the loading surface;
a gas distribution unit including injection holes facing the mounting table;
a gas supply unit configured to supply process gas through the gas distribution unit;
a first power supply unit configured to apply a first voltage to the electrode; and
a second power supply unit configured to apply a second voltage to the heater,
wherein the dielectric layer includes a lower material layer, an intermediate material layer, and an upper material layer, sequentially stacked on the loading surface,
the intermediate material layer has a third thickness, greater than each of a first thickness of the lower material layer and a second thickness of the upper material layer, and
the intermediate material layer has a third dielectric constant, greater than each of a first dielectric constant of the lower material layer and a second dielectric constant of the upper material layer.

2. The substrate processing apparatus of claim 1, wherein the third thickness of the intermediate material layer is 60% or more of a total thickness of the dielectric layer.

3. The substrate processing apparatus of claim 2, wherein the total thickness of the dielectric layer is in a range of 1 μm to 10 μm.

4. The substrate processing apparatus of claim 1, wherein the loading surface has a first surface, and a second surface recessed from the first surface, and
the protrusions are on the second surface.

5. The substrate processing apparatus of claim 4, wherein the insulator further comprises a seal band at a corner of the second surface, and configured to support an edge of the substrate.

6. The substrate processing apparatus of claim 5, wherein the dielectric layer extends along surfaces of the protrusions and a surface of the seal band.

7. The substrate processing apparatus of claim 1, wherein the third dielectric constant is twice or more than each of the first dielectric constant and the second dielectric constant.

8. The substrate processing apparatus of claim 1, wherein the intermediate material layer comprises at least one of silicon nitride (Si₃N₄), aluminum oxide (Al₂O₃), zirconia (ZrO₂), and hafnium oxide (HfO₂).

9. The substrate processing apparatus of claim 1, wherein the lower material layer and the upper material layer comprise silicon dioxide (SiO).

10. The substrate processing apparatus of claim 1, wherein the insulator comprises at least one of aluminum nitride (AlN), aluminum oxide (Al₂O₃), and boron nitride (BN).

11. A substrate processing apparatus, comprising:
a mounting table having a pocket region in which a substrate is loaded, the mounting table including an insulator having protrusions and a seal band in the pocket region;
an electrode embedded in the insulator;
a dielectric layer conformally extending along a surface of each of the protrusions and the seal band;
a gas distribution unit including injection holes facing the mounting table;
a gas supply unit configured to supply process gas through the gas distribution unit; and
a power supply unit configured to apply a voltage to the electrode,
wherein the dielectric layer includes a lower material layer, an intermediate material layer, and an upper material layer, and
a thickness of the intermediate material layer is greater than a sum of a thickness of the lower material layer and a thickness of the upper material layer.

12. The substrate processing apparatus of claim 11, wherein the insulator further comprises a spaced surface between adjacent ones of the protrusions, and between the seal band and the protrusions, and
the dielectric layer extends along the spaced surface.

13. The substrate processing apparatus of claim 11, wherein the substrate is in contact with the dielectric layer covering an upper surface of each of the protrusions and the seal band.

14. The substrate processing apparatus of claim 11, wherein a height of each of the protrusions and the seal band is in a range of 20 μm to 40 μm, and
a total thickness of the dielectric layer is in a range of 1 μm to 5 μm.

15. The substrate processing apparatus of claim 14, wherein a thickness of the intermediate material layer is in a range of 70% to 80% of the total thickness of the dielectric layer.

16. The substrate processing apparatus of claim 11, wherein the insulator comprises aluminum nitride (AlN),
the lower material layer and the upper material layer comprise silicon dioxide (SiO₂), and
the intermediate material layer comprises silicon nitride (Si₃N₄).

17. The substrate processing apparatus of claim 11, wherein the voltage is a direct current voltage of 1000V or less.

18. A substrate processing apparatus, comprising:
a mounting table including an insulator having a loading surface on which a substrate is loaded;
an electrode and a heater embedded in the insulator;
a dielectric layer covering the loading surface;
a gas distribution unit including injection holes facing the mounting table;
a gas supply unit configured to supply process gas through the gas distribution unit;
a first power supply unit configured to apply a first voltage to the electrode; and
a second power supply configured to apply a second voltage to the heater,
wherein the dielectric layer includes a lower material layer, an intermediate material layer, and an upper material layer, sequentially stacked on the loading surface,
a thickness of the intermediate material layer is greater than a thickness of the lower material layer and a thickness of the upper material layer, and
hardness of the intermediate material layer is greater than hardness of the upper material layer.

19. The substrate processing apparatus of claim 18, wherein the insulator comprises aluminum nitride (AlN),
the lower material layer and the upper material layer comprise silicon dioxide (SiO₂), and
the intermediate material layer comprises silicon nitride (Si₃N₄).

20. The substrate processing apparatus of claim 18, wherein the dielectric layer covers an entirety of the loading surface.
